(19) United States
(12) Patent Application Publication
(10) Pub. No.: US 2015/0104246 A1
(43) Pub. Date: Apr. 16, 2015

(54) QUICK-DETACHABLE FASTENING ASSEMBLY

(71) Applicants: INVENTEC CORPORATION, TAIPEI CITY (TW); Inventec (Pudong) Technology Corporation, Shanghai (CN)

(72) Inventor: Tai-Yi CHIANG, TAIPEI CITY (TW)

(73) Assignees: INVENTEC CORPORATION, TAIPEI CITY (TW); Inventec (Pudong) Technology Corporation, Shanghai (CN)

(21) Appl. No.: 14/228,249

(22) Filed: Mar. 27, 2014

(30) Foreign Application Priority Data
Oct. 10, 2013 (CN) 201310470571.7

(51) Int. Cl. F16B 21/08; H05K 7/14

(52) U.S. Cl. CPC F16B 21/08; H05K 7/1485
USPC 403/330

(57) ABSTRACT

The disclosure discloses a quick-detachable fastening assembly including a fixing base, a buckling member, and a plug. The fixing base has an opening and a receiving trough and further has a necking portion in the receiving trough. The buckling member includes a pipe body and a plurality of resilient arms connected to an end of the pipe body. Each of the resilient arms has a buckling block. When the buckling blocks pass through the necking portion, the resilient arms are elastically deformed to move closer to each other. After the buckling blocks are received in the receiving trough, the resilient arms elastically restore. The plug is slidably inserted into the pipe body. When the plug slides relative to the pipe body to extend to the tail ends of the resilient arms, the tail ends abut against the outer surface of the plug.

### RELATED APPLICATIONS

This application claims priority to Chinese Application Serial Number 201310470571.7, filed Oct. 10, 2013, which is herein incorporated by reference.

### BACKGROUND

1. Technical Field

The present invention relates to a quick-detachable fastening assembly.

2. Description of Related Art

With the rapid advancement of information technology, computers are widely used electronic devices. Electronic devices on consumers market such desktop, notebook or server need various expansion adapter cards to connect host computer with peripheral devices. For example, the expansion adapter cards are interface cards to connect host computer and peripheral devices so that the host computer can exchange information and communication signals with the peripheral devices. Thus, the peripheral devices can execute their functionality.

Conventional electronic devices, motherboard usually provides a plurality slots for interface adapter cards such as graphic adapter cards, sound adapter cards, network adapter cards, Universal Serial Bus (USB) adapter cards, and memory sticks to expand functionality of the electronic devices. Presently, Peripheral Component Interconnect (PCI) interface has become standard bus for connecting motherboard of host computer with peripheral hardware. That is, most widely used interface adapter cards are PCI-compatible adapter cards, and most interface adapter slots in the host computers are PCI-compatible slots.

Generally speaking, to conveniently assemble server and make use of server internal space, the PCI adapter cards may be installed at the servers through support bracket (what so called “airplane bracket”). However, quick detachable fasteners used in adapter card backplates usually need larger operation window. Thus, if internal space of server case is limited, PCI adapter cards with conventional quick detachable fasteners can't be installed.

### SUMMARY

The disclosure discloses a quick-detachable fastening assembly that includes a fixing base, a buckling member, and a plug. The fixing base has an opening and a receiving trough, and further has a necking portion in the receiving trough. The buckling member includes a pipe body and a plurality of resilient arms. The pipe body has a first end, and the resilient arms are connected to the first end of the pipe body. A tail end of each of the resilient arms has a buckling block. When the buckling blocks pass through the necking portion, the resilient arms are elastically deformed to move closer to each other. After the buckling blocks are accommodated in the receiving trough, the resilient arms elastically restore. The plug is slidably inserted into the pipe body. When the plug slides relative to the pipe body to extend to the tail ends of the resilient arms, the tail ends of the resilient arms abut against the outer surface of the plug.

According to one embodiment of the present invention, the pipe body further includes a second end, and the buckling member further includes a first buckling structure. The first buckling structure is positioned at the pipe body and neighboring to the second end of the pipe body. The plug has a second buckling structure which is positioned between the first end and the second end. The plus slides relative to the pipe body so that the first buckling structure and the second buckling structure engage each other, and the plug moves away from the tail end of the resilient arms.

According to one embodiment of the present invention, the first buckling structure is positioned on an outer surface of the pipe body. The plug includes a shaft, a push portion, and a hand-held portion. The shaft may slidably be inserted into the pipe body. When the shaft of the plug moves relative to the pipe body and adjacent to the tail ends of the resilient arms, the tail ends of the resilient arms abuts against the outer surface of the shaft of the plug. The push portion is connected with the shaft and positioned out of the pipe body and adjacent to the second end. The hand-held portion is formed with the push portion and extends out of the pipe body. The second buckling structure is positioned at the hand-held portion, and the first buckling structure is retained between the push portion and the second buckling structure. When the plug moves relative to the pipe body to make the second end abut against the push portion, the shaft extends to the tail ends of the resilient arms.

According to one embodiment of the present invention, the resilient arms extend in a direction which is substantially parallel to axis of the pipe body, and the buckling block extends in a direction which is away from the axis of the pipe body.

According to one embodiment of the present invention, the necking portion has a first tapered surface which is neighboring to the opening. The first tapered surface shrinks toward the bottom of the receiving trough, and each of the buckling blocks has a first slope. The first slope inclines toward the axis of the pipe body and away from the pipe body along the axis. When the buckling blocks pass through the necking portion and move into the receiving trough, the first tapered surface pushes the first slope so that the resilient arms are elastically deformed and move closer each other.

According to one embodiment of the present invention, the necking portion further has a second tapered surface which is neighboring to the bottom of the receiving trough. The second tapered surface shrinks toward the opening of the fixing base, and each of the buckling blocks has a second slope. The second slope is located between the pipe body and the first slope, and inclines toward the axis of the pipe body and the pipe along the axis. When the buckling blocks pass through the necking portion and move away from the receiving trough, the second tapered surface pushes the second slope so that the resilient arms are elastically deformed and move closer each other.

In summary, according to the present invention, when the quick-detachable fastening assembly is installed at motherboard of servers by support bracket, the buckling blocks of the resilient arms are fit in the fixing base of the substrate. Then, the plug is pushed toward the fixing base so that the buckling blocks abuts against the outer surface of the plug, and the buckling blocks are prevent from sliding through the necking portion of the fixing base and move away from the fixing base. While detached, the plug may be pulled away from the fixing base so that the buckling blocks lose contact with the fixing base. The buckling blocks are moved through the necking portion and pulled away from the fixing base. Then, the card backplate is separate from the substrate. Thus, the quick-detachable fastening assembly of the present invention may be applied in server with limiting space, and the way how to attach and detach the assembly is the same as that of conventional adapter cards, and is a straight-forward design.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective and exploded view card backplate and a substrate according to the present invention;

FIG. 2A is a perspective view of a fixing base, a buckling member, and a plug of the quick-detachable fastening assembly according to one embodiment of this invention;

FIG. 2B is an exploded view of the quick-detachable fastening assembly of FIG. 2A;

FIG. 3A is a cross-section of the card backplate and the substrate with the line 3A-3A′ of FIG. 1 when the buckling blocks are not fit in the fixing base yet;

FIG. 3B is another cross-section of the card backplate and the substrate with the line 3A-3A′ of FIG. 1 when the buckling blocks fit in the fixing base; and

FIG. 3C is another cross-section of the card backplate and the substrate with the line 3A-3A′ of FIG. 1 when the plug is pushed downwardly so that the shaft of the plug extends to the tail ends of the resilient arms.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

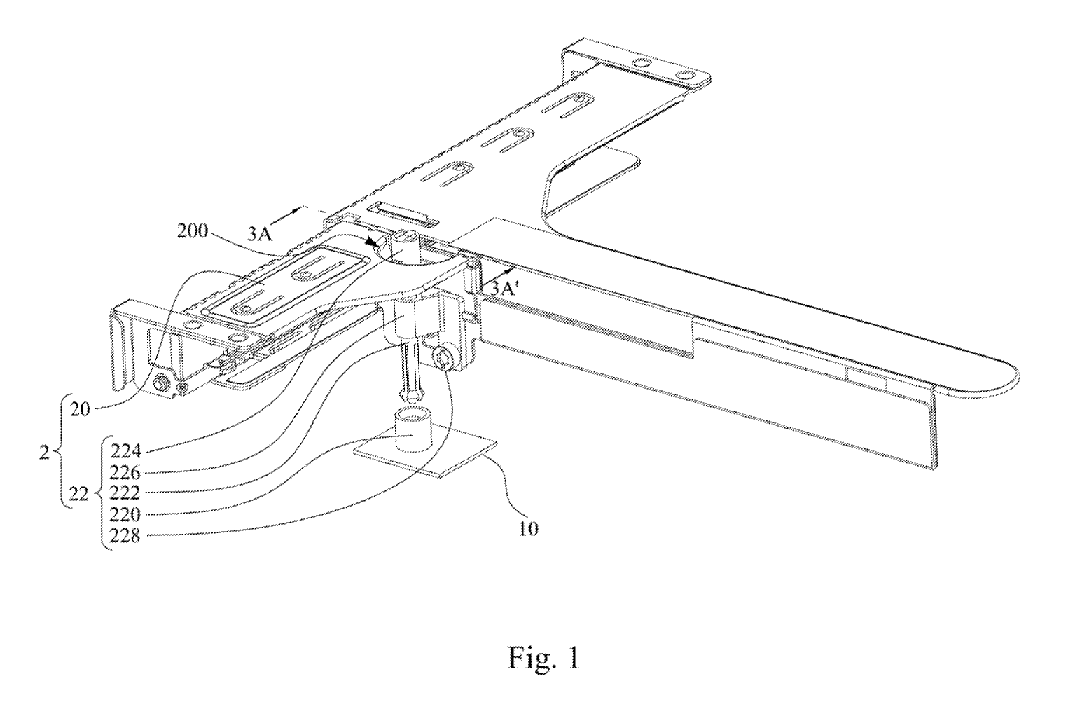

Referring to FIG. 1, it illustrates a perspective and exploded view of card backplate 2 and a substrate 10 according to the present invention.

As shown in FIG. 1, according to the present invention, the card backplate 2 is detachably installed at the substrate 10. The card backplate 2 includes a support bracket 20 (what so called “airplane bracket”) and a quick-detachable fastening assembly 22. The support bracket 20 of the card backplate 2 may engage and support PCI adapter card (not shown), and the PCI adapter card may be installed at the substrate 10 by the card backplate 2. The substrate 10 may be part of server case (not shown), and the present invention is not limited to this. The quick-detachable fastening assembly 22 of the card backplate 2 includes a fixing base 220, a buckling member 222, a plug 224, a hinge 226, and a screw 28. The following description is directed to structure, function of components and interconnections among the components.

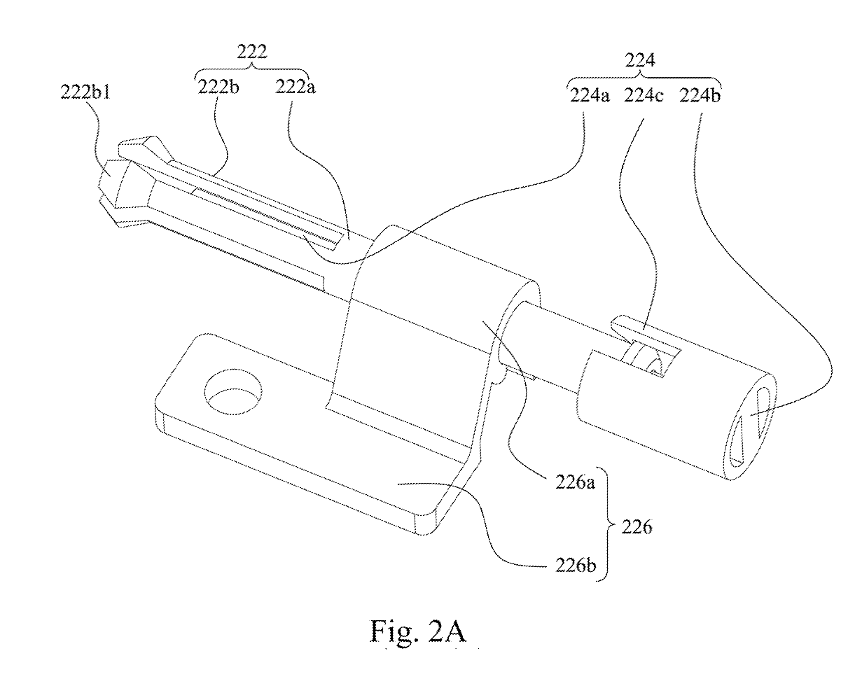

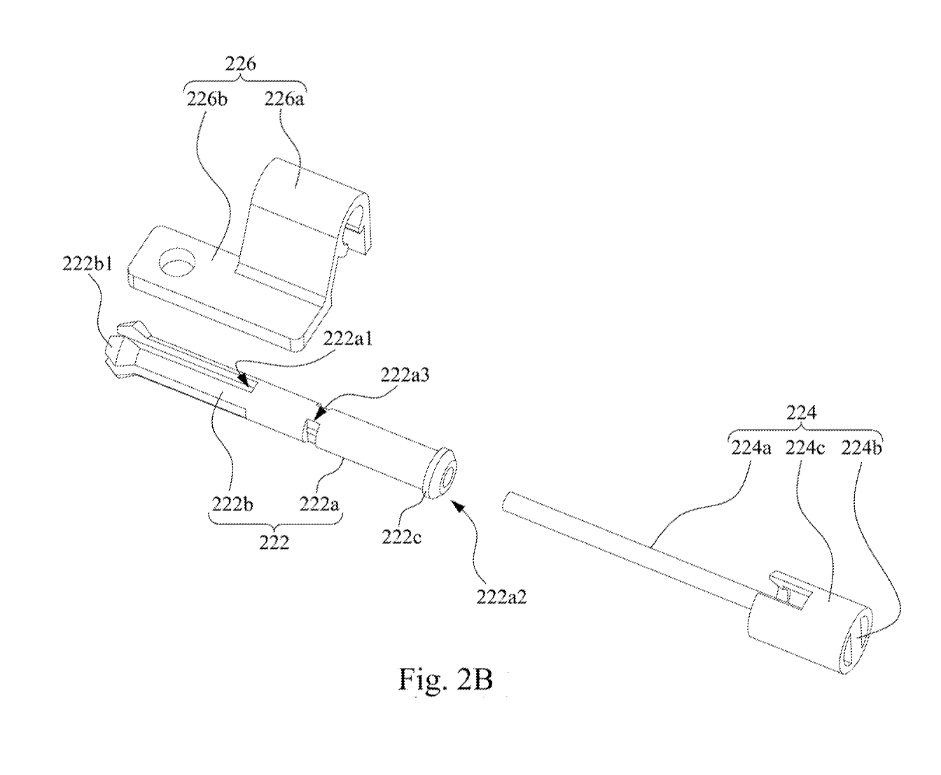

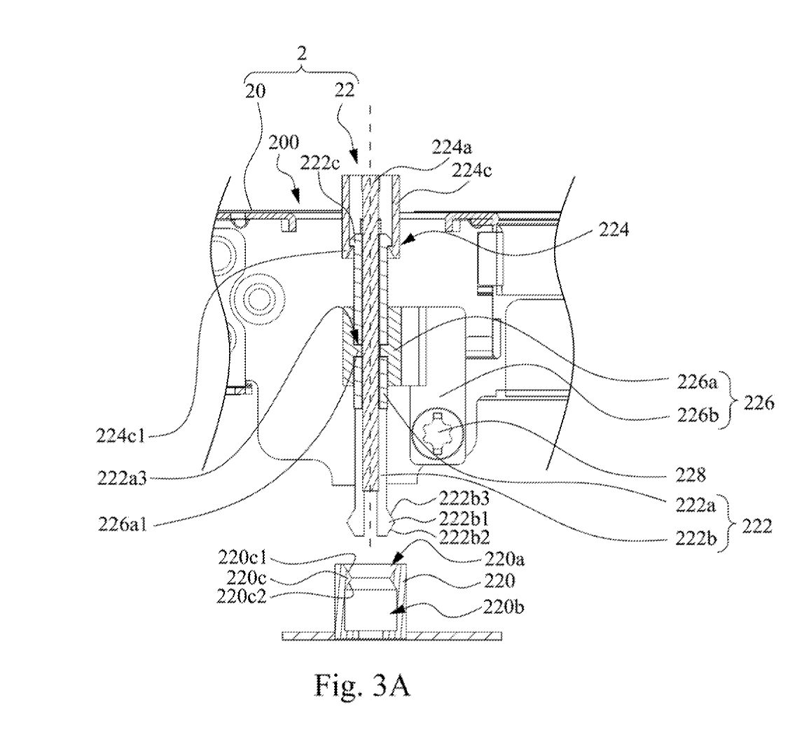

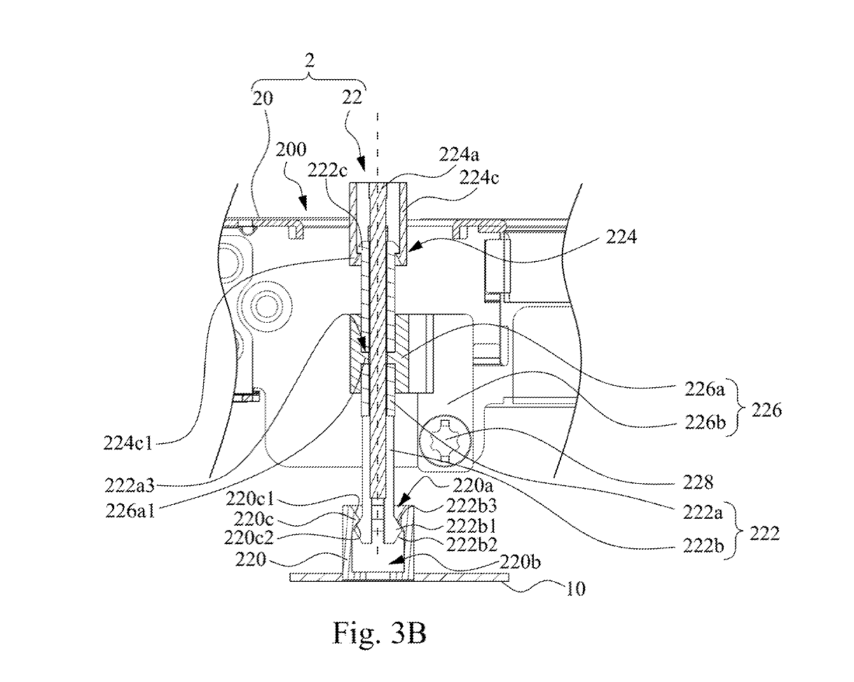

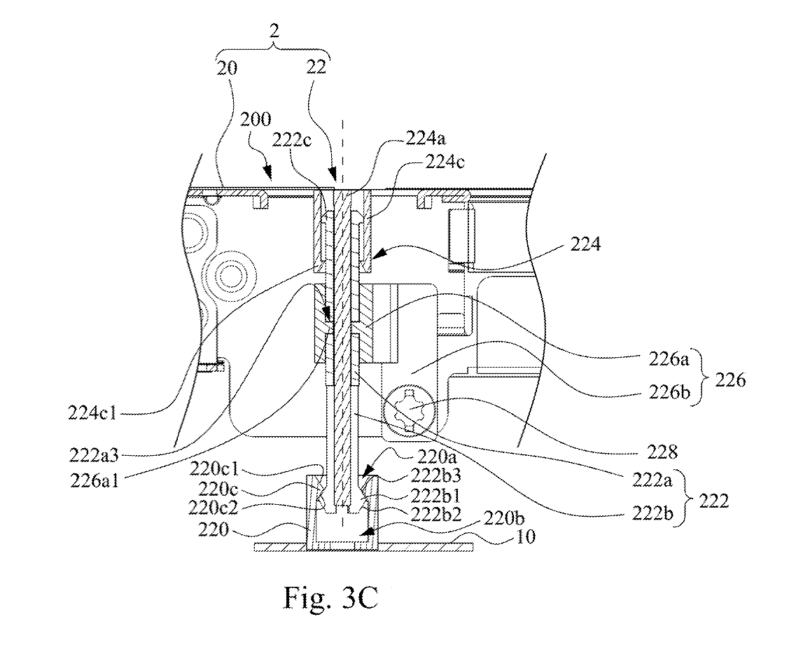

Please refer to FIGS. 2A, 2B, and 3A. FIG. 2A illustrates a perspective view of the fixing member 222, the plug 224, and the hinge 226 of the quick-detachable fastening assembly 22 according to one embodiment of this invention. FIG. 2B illustrates an exploded and perspective view of the quick-detachable fastening assembly 22 of FIG. 2A. FIG. 3A illustrates a cross-section of the card backplate 2 and the substrate 10 with the line 3A-3A′ of FIG. 1.

As shown in FIGS. 2A-3A, according to the embodiment, the fixing base 220 of the quick-detachable fastening assembly 22 is positioned at the substrate 10, and includes an opening 220a and a receiving trough 220b with the opening 220a. A necking portion 220c is formed at the receiving trough 220b of the fixing base 220. The buckling member 222 of the quick-detachable fastening assembly 22 includes a pipe body 222a and a plurality of resilient arms 222b. The pipe body 222a includes a first end 222a1 and a second end 222a2 (as shown in FIG. 2B). The resilient arms 222b are formed with the first end 222a1. A buckling block 222b1 is formed at each tail end of the resilient arms 222b. The resilient arms 222b extend in a direction that is substantially parallel to the axis of the pipe body 222a, and the buckling block 222b1 extends outwardly relative to the axis of the pipe body 222a. The plug 224 of the quick-detachable fastening assembly 22 is sideably inserted into the pipe body 222a. The hinge 226 of the quick-detachable fastening assembly 22 is connected with the buckling member 222, which is installed to the support bracket 20.

Please refer to FIGS. 3B and 3C. FIG. 3B is another cross-section of FIG. 3A when the buckling blocks 222b1 is fit in the fixing base 220. FIG. 3C is another cross-section of FIG. 3A when the plug 224 is pushed downwardly so that the shaft 224a of the plug 224 extends to the tail ends of the resilient arms 222b.

As shown in FIGS. 3A-3C and FIG. 2B, according to the embodiment, when the buckling block 222b1 is fit to the opening 220a of the fixing base 220 and passes through the necking portion 220c, the resilient arms 222b are elastically deformed to move closer. After the buckling blocks 222b1 are fit in the receiving trough 220b, the resilient arms 222b restore, as described in FIGS. 3A-3B. Afterwards, when the plug 224 of the quick-detachable fastening assembly 22 relative to the pipe body 222a of the buckling member 222 extends to the tail end of the resilient arms 222b, the tail ends of the resilient arms 222b abut against the outer surface of the plug 224, as described in FIGS. 3B-3C.

Furthermore, the plug 224 of the quick-detachable fastening assembly 22 includes a shaft 224a, a push portion 224b, and hand-held portion 224c. The shaft 224a of the plug 224 is slidably fit in the pipe body 222a of the buckling member 222. When the shaft 224a of the plug 224 relative to the pipe body 222a of the buckling member 222 extends to the tail ends of the resilient arms 222b, the tail ends of the resilient arms 222b abut against the outer surface. Thus, the resilient arms 222b are not subjected to external forces and elastically deformed toward the axis of the pipe body 222a so that the buckling block 222b1 does not move away because of the necking portion 220c of the fixing base 220.

The push portion 224b of the plug 224 is connected to the shaft 224a and located out of the pipe body 222a and adjacent to the second end 222a2 of the pipe body 222a. The hand-held portion 224c of the plug 224 is formed with the push portion 224b and extends out of the outer surface of the pipe body 222a so that the plug 224 may be manually moved relative to the buckling member 222. The buckling member 222 further includes a first buckling structure 222c. The first buckling structure 222c is defined at the pipe body 222a and adjacent to the second end 222a2. The plug 224 includes a second buckling structure 224c1 that is formed at the hand-held portion 224c. The second buckling structure 224c1 is located between the first end 222a1 and the second end 222a2 of the pipe body 222a, and the first buckling structure 222c is retained between the push portion 224b and the second buckling structure 224c1 of the plug 224.

Therefore, when the plug 224 moves relative to the pipe body 222a of the buckling member 222 to make the first buckling structure 222c of the buckling member 222 engage with the second buckling structure 224c1 of the plug 224, the plug 224 moves away from the tail end of the resilient arms 222b (as shown in FIG. 3A). That is, when the first buckling structure 222c of the buckling member 222 engages the second buckling structure 224c1 of the plug 224, the plug 224 is prevent from moving away the second end 222a2 of the pipe body 222a. When the plug 224 slides relative to the pipe body 222a of the buckling member 222 to make the second end 222a2 of the pipe body 222a abut against the push portion 224b of the plug 224, the shaft 224a of the plug 224 extends to the tail end of the resilient arms 222b. That is, when the second end 222a2 of the pipe body 222a is prevent from moving by the push portion 224b of the plug 224, the shaft 224a of the plug 224 extends out of the tail end of the resilient arms 222b with accuracy and the plug 224 is prevent moving away from the first end 222a1 of the pipe body 222a.

It is noted that although the first buckling structure 222c of the buckling member 222 is defined at the outer surface of the pipe body 222a in accordance with one embodiment, the present invention is not limited to this. According to another embodiment, the first buckling structure 222c of the buckling member 222 may be also defined at the inner surface of the pipe body 222a, the shaft 224a of the plug 224 includes a keyway (not shown) for engaging the first buckling structure 222c. Thus, the plug 224 is also prevented moving away from the second end 222a2 of the pipe body 222a, and besides, the push portion 224b of the plug 224 may be omitted.

As also shown in FIGS. 3A-3C, according to one embodiment, the necking portion 220c of the fixing base 220 has a first tapered surface 220c1. The first tapered surface 220c1 of the necking portion 220c is adjacent to the opening 220a, and shrinks toward the bottom of the receiving trough 220b. Each of resilient arms 222b has a buckling block 222b1 with a first slope 222b2. The first slope 222b2 inclines toward the axis of the pipe body 222a and away from the pipe body 222a along the axis. When the buckling block 222b1 passes through the necking portion 220c and fits to the receiving trough 220b (as shown in FIGS. 3A-3B), the first tapered surface 220c1 of the necking portion 220c pushes the first slope 222b2 of the buckling block 222b1 so that the resilient arms 222b elastically deforms toward axis of the pipe body 222a.

Furthermore, the necking portion 220c of the fixing base 220 further includes a second tapered surface 220c2. The second tapered surface 220c2 of the necking portion 220c is adjacent to and shrinks toward the bottom of the receiving trough 220b. Each of the resilient arms 222b has a buckling block 222b1 with a second slope 222b3. The second slope 222b3 is defined between the pipe body 222a and the first slope 222b2 and inclines toward the axis of the pipe body 222a and the pipe 222a along the axis. When the buckling blocks 222b1 pass through the necking portion 220c and move away from the receiving trough 220b (as shown in FIGS. 3A-3B), the second tapered surface 220c2 of the necking portion 220c pushes the second slopes 222b3 of the buckling blocks 222b1 so that the resilient arms 222b are elastically deformed toward the axis of the pipe body 222a and move closer.

As described above, with the interaction between the first tapered surface 220c1 of the necking portion 220c and the first slope 222b2 of the buckling block 222b1, and between the second tapered surface 220c2 of the necking portion 220c and the second slope 222b3 of the buckling block 222b1, the buckling block 222b1 may smoothly pass through the necking portion 220c and fit to the receiving trough 220b, or move away from the receiving trough 220b.

As shown in FIGS. 1 and 3A, according to the embodiment, a groove 222a3 is defined at outer surface of the pipe body 222a of the buckling member 222. The hinge 226 includes a receiving portion 226a and a screwing portion 226b. The receiving portion 226a of the hinge 226 is adapted to cover the outer surface of the pipe body 222a and has a protuberance 226a1. The protuberance 226a1 of the receiving portion 226a is fit to the groove 222a3 of the pipe body 222a so that the buckling member 222 and the hinge 226 are coupled altogether. The screwing portion 226b of the hinge 226 is connected with the receiving portion 226a and is attached to the support bracket 20 by the screw 228. Thus, the support bracket 20 is quickly assembled with or detached from the substrate 10 by the quick-detachable fastening assembly 22.

It is understood that the quick-detachable fastening assembly 22 of the present invention is operated in the same direction as that of assembly or detachment of the card backplate 2. Thus, an assembly hole 200 is provided and is not huge but enough to assemble the quick-detachable fastening assembly 22 to the support bracket 20.

Because the foregoing embodiments deliberates in detail, it is obvious when the quick-detachable fastening assembly of the present invention assembled to the substrates of the server, the buckling blocks of the resilient arms are fit to the fixing base of the substrate and the plug is pushed downwardly toward the fixing base so that the buckling blocks surround and abuts the outer surface of the plug. It prevents the buckling blocks from moving through the necking portion of the fixing base so that the buckling blocks move away from the fixing base. While detached, the plug may be pulled away from the fixing base so that the buckling blocks lose contact with the fixing base. The buckling blocks are moved through the necking portion and pulled away from the fixing base. Then, the card backplate is separate from the motherboard. Thus, the quick-detachable fastening assembly of the present invention may be applied in server with limiting space, and the way how to attach and detach the assembly is the same as that of conventional adapter cards, and is straight-forward.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A quick-detachable fastening assembly, comprising:
a fixing base having an opening and an receiving trough, the receiving trough having a necking portion;
a buckling member having a pipe body and a plurality of resilient arms, a first end of the pipe body connected to the resilient arms, a tail end of each of the resilient arms having a buckling block, wherein when the buckling blocks pass through the necking portion, the resilient arms are elastically deformed to move closer to each other, and after the buckling blocks are accommodated in the receiving trough, the resilient arms elastically restore; and
a plug slidably inserted into the pipe body, wherein when the plug slides relative to the pipe body to extend to the tail ends of the resilient arms, the tail ends of the resilient arms abut against the outer wall of the plug.

2. The quick-detachable fastening assembly of claim 1, wherein the pipe body further comprises a second end, the buckling member further comprises a first buckling structure disposed at the pipe body and adjacent to the second end of the pipe body, the plug comprises a second buckling structure disposed between the first end and the second end, wherein when the plug slides relative to the pipe body to make the first buckling structure and the second buckling structure engage with each other, the plug moves away from the tail ends of the resilient arms.

3. The quick-detachable fastening assembly of claim 2, wherein the first buckling structure is disposed on an outer surface of the pipe body, and the plug comprises:
a shaft slidably inserted into the pipe body, wherein when the shaft of the plug moves relative to the pipe body to extend to the tail ends of the resilient arms, the tail ends of the resilient arms abuts against the outer surface of the shaft of the plug;
a push portion connected with the shaft, located out of the pipe body, and adjacent to the second end; and
a hand-held portion connected with the push portion and extending out of the pipe body, wherein the second buckling structure is disposed at the hand-held portion, the first buckling structure is retained between the push portion and the second buckling structure, and when the plug moves relative to the pipe body to make the second end abut against the push portion, the shaft extends to the tail ends of the resilient arms.

4. The quick-detachable fastening assembly of claim 1, wherein the resilient arms extend in a direction that is substantially parallel to axis of the pipe body, and the buckling block extends outwardly from the axis of the pipe body.

5. The quick-detachable fastening assembly of claim 4, wherein the necking portion has a first tapered surface which is neighboring to the opening, and the first tapered surface shrinks toward the bottom of the receiving trough, each of the buckling blocks has a first slope that inclines toward the axis of the pipe body and away from the pipe body along the axis, and when the buckling blocks pass through the necking portion and move into the receiving trough, the first tapered surface pushes the first slope so that the resilient arms are elastically deformed and move closer.

6. The quick-detachable fastening assembly of claim 5, wherein the necking portion further comprises a second tapered surface that is neighboring to the bottom of the receiving trough, the second tapered surface shrinks toward the opening of the fixing base, each of the buckling blocks has a second slope that is located between the pipe body and the first slope and inclines toward the axis of the pipe body and the pipe along the axis, and when the buckling blocks pass through the necking portion and move away from the receiving trough, the second tapered surface pushes the second slope so that the resilient arms are elastically deformed and move closer.
